(19) United States
(12) Patent Application Publication
(10) Pub. No.: US 2003/0063689 A1
(43) Pub. Date: Apr. 3, 2003

(54) Apparatus for receiving digital data from a transmitter transmitting without contact and method of matching the apparatus to characteristics of the transmitter

(76) Inventor: Christian Schneckenburger, Hohenkirchen (DE)

Correspondence Address: LERNER AND GREENBERG, P.A., Post Office Box 2480, Hollywood, FL, 33022-2480, US

(21) Appl. No.: 10/252,452

(22) Filed: Sep. 23, 2002

Related U.S. Application Data
(63) Continuation of application No. PCT/DE01/01085, filed on Mar. 21, 2001.

(30) Foreign Application Priority Data
Mar. 22, 2000 (EP) 00 106 220.7

(51) Int. Cl. H03K 9/00; H04L 27/06

(52) U.S. Cl. 375/316

(57) ABSTRACT

An apparatus for receiving digital data from a transmitter transmitting without contact includes an analog receiving unit and a decoder connected downstream of the analog receiving unit. A signal former is provided to apply a test signal profile to the analog receiving unit. Further, a calibration unit is provided which determines parameter values on the basis of the signal generated by the analog receiving unit. The decoder can be matched to the analog receiving unit and/or the transmitter using the parameter values. A method of matching such an apparatus to characteristics of a transmitter.

### CROSS-REFERENCE TO RELATED APPLICATION

This application is a continuation of copending International Application No. PCT/DE01/01085, filed Mar. 21, 2001, which designated the United States and was not published in English.

### BACKGROUND OF THE INVENTION

### FIELD OF THE INVENTION

The invention relates to an apparatus for receiving digital data from a transmitter that transmits without contact, which includes an analog receiving unit and a decoder connected downstream of the analog receiving unit. The invention relates to a method of matching such an apparatus to characteristics of the transmitter.

In the following text, the apparatus for receiving digital data from a transmitter that transmits without contact is also understood to include a device which can also transmit data to the transmitter. However, the subject of the invention relates only to the part which is needed to receive the data. Thus, the transmitting unit will not be discussed specifically in the following text.

Digital signals from transmitters that transmit without contact are highly distorted by the analog receiving unit of such an apparatus as a result of filters, amplifiers and decoupling elements. The decoder connected downstream of the analog receiving unit is able to decode the digital signals only to a restricted extent and with high error rates, since the original signal is subjected to delay times in the analog receiving unit. Likewise, the original signal may contain signal overswings or attenuation after passing through the analog receiving unit. The transmitters considered herein are, for example, smart cards, which exchange their data and power with the read/write device via an antenna.

Therefore, the properties of the analog receiving unit must be matched to the properties of the transmitter. Only then, it is ensured that the decoder can decode the digital signals from the transmitter with a sufficiently high integrity. The decoders (used at present) can be matched to the behavior of the analog receiving unit by changing the characteristics of the decoder (i.e., calibrated), in order to minimize possible error rates.

However, the procedure used in the context of such conventional decoders is based on an entirely manual adaptation of the previously determined parameters. Further, the exact determination of the parameters is currently not possible. It is merely possible to estimate whether the newly set parameters have a more beneficial or more detrimental effect on the error rate. The parameters determined are then loaded into a register of the decoder. Another possible way of adapting the decoder is to vary its characteristics by using trim potentiometers.

Using different transmitters, for example, for different card types, entails different parameter values for a decoder described above. If a reader is to be configured for various transmitter types, then the decoder can be set only to an average for all the transmitter types. However, in this way, the optimum decoder result will never be achieved.

A further disadvantage of the conventional readers is that each analog receiving unit has different characteristics due to component scatter. Therefore, the calibration has to be performed separately for each receiving unit.

### SUMMARY OF THE INVENTION

It is accordingly an object of the invention to provide an apparatus for receiving digital data from a transmitter transmitting without contact and a method of matching such an apparatus to characteristics of the transmitter, which overcome the hereinafore-mentioned disadvantages of the heretofore-known devices and methods of this general type.

With the foregoing and other objects in view, there is provided, in accordance with the invention, an apparatus for receiving digital data from a transmitter transmitting without contact including an analog receiving unit, a decoder connected downstream of the analog receiving unit and a signal former to supply a test signal profile to the analog receiving unit. The apparatus further includes a calibration unit, which, on the basis of the signal generated by the analog receiving unit, determines parameters with which the decoder can be matched to the analog receiving unit and/or the transmitter.

This enables an automatic calibration of the reader to the characteristics of the analog receiving unit and the characteristics of the transmitter used. Therefore, the manual matching of the decoder to the analog receiving unit can be dispensed with. The system is additionally capable of reacting to changed conditions, such as new types of transmitters and changed distances between the transmitter and the apparatus. The calibration is performed in “the background” of the reader. Recourse to the existing hardware can substantially be had.

A further advantage is that the invention performs automatic matching to the parameters of the analog receiving unit and/or the transmitter, in the event of the frequent occurrence of errors.

Therefore, the invention converts a reader for transmitters that transmit without contact from a statically fixed receiver to a dynamically adaptive system. This is based on the concept of using a signal former to generate the response signal from a transmitter that transmits without contact in the antenna field of the apparatus. This response signal, which is distorted by the analog receiving unit, permits a comparison with the generated test signal profile, by which the decoder can be set to an optimum detection level.

In accordance with another feature of the invention, the calibration unit contains a memory for typical signal profiles of the transmitter. The calibration unit is connected to the signal former. Each stored signal profile represents a different transmitter type. For example, in the field of smart cards, two different types (type A and type B) with different transmission protocols are defined by ISO 14443. The respective signal profile characteristic for the type of smart card is stored in the calibration unit. This enables the automatic matching of the decoder to different transmitter types.

In accordance with a further feature of the invention, the calibration unit is connected to a signal input and to a signal output of the decoder. Thus, the calibration unit can evaluate both the encoded and the decoded test signal profile for analysis.

In accordance with an added feature of the invention, the calibration unit is advantageously connected to a parameter register coupled to the decoder. Following the analysis of a test signal profile and the determination of the parameter values needed to match the decoder, the parameter values can be loaded into the parameter register. The decoder can refer to the parameter values.

In accordance with an additional feature of the invention, the parameter register is a part of the decoder.

In accordance with yet another feature of the invention, the calibration unit has a parameter memory. Thus, the parameters can be stored temporarily in the memory during an iterative approximation to the optimum parameters.

In accordance with yet a further feature of the invention, the signal former constitutes an electrical equivalent circuit of the transmitter, which is connected to the input of the analog receiving unit. Therefore, the signal former is an equivalent circuit of the antenna of the transmitter. The generation of the test data signal takes place in the calibration unit.

With the objects of the invention in view, there is also provided a method for matching an apparatus for receiving digital data to the characteristics of the transmitter including the steps of a) providing a test signal profile; b) feeding the test signal profile into the analog receiving unit; c) forwarding the possibly distorted signal profile to the calibration unit, d) analyzing the possibly distorted signal profile and determining parameter values; e) loading the parameter values into the parameter register. If necessary, steps a) to e) are repeated as step f).

In accordance with another feature of the invention, the method includes step g), in which, a comparison between the output signal of the decoder and the test signal profile is carried out.

In accordance with a further feature of the invention, in the event of a deviation between the output signal and the test signal profile, the steps a) to g) are repeated.

In accordance with an added feature of the invention, the test signal profile is stored in the calibration unit and is supplied to the signal former. Further, the signal former supplies the test signal profile to the signal input of the analog receiving unit.

In accordance with an additional feature of the invention, the test signal profile reproduces a typical signal profile of the transmitter. Various test signal profiles can be stored in the calibration unit or another apparatus. In accordance with yet another feature of the invention, the test signal profile includes an item of information for changing the level of attenuation. In this way, a different distance between the transmitter and the analog receiving unit can be simulated. A change in the level of attenuation can be effected by the edges in the varied test signal profile. Alternatively, in the signal former (which represents an equivalent circuit for the antenna of the transmitter), a change in the level of attenuation may be simulated by modifying the parameters of subassembly components.

In accordance with a concomitant feature of the invention, the analysis (of the test signal profile in the analog receiving unit) and determining (the parameter values) step includes, determining the propagation time of the test signal profile in the analog receiving unit. Furthermore, it is conceivable to determine overswings and the initial transient time of the test signal profile. In addition, a variance of signal widths and/or a variance of signal shifts can be used for the analysis.

Other features which are considered as characteristic for the invention are set forth in the appended claims.

Although the invention is illustrated and described herein as embodied in an apparatus for receiving digital data from a transmitter transmitting without contact and a method of matching such an apparatus to characteristics of the transmitter, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic and block diagram of an apparatus for receiving digital data from a transmitter transmitting without contact according to the invention; and

FIG. 2 is a block diagram illustrating the calibration unit of FIG. 1 in more detail.

### DESCRIPTION OF THE PREFERRED EMBODIMENTS

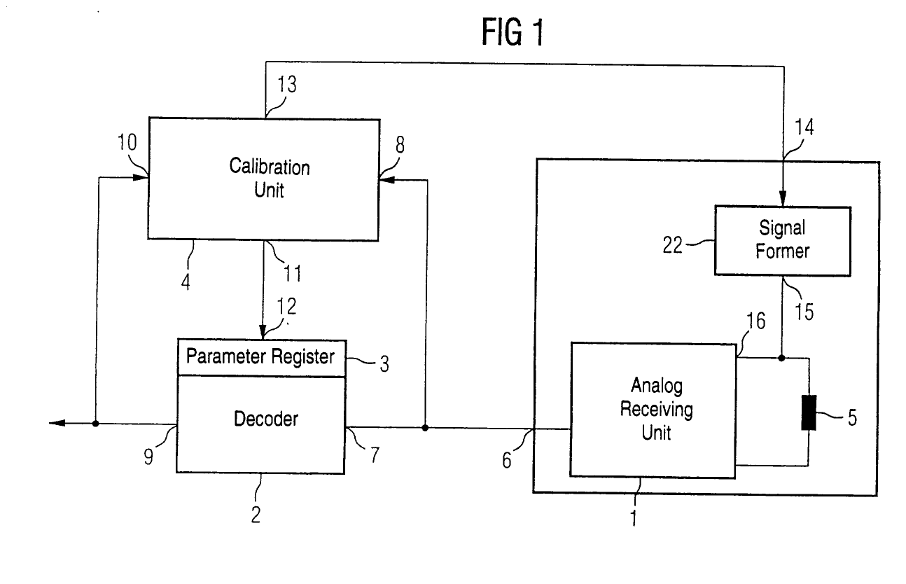

Referring now to the figures of the drawings in detail and first, particularly to FIG. 1 thereof, there is shown an apparatus for receiving digital data from a transmitter that transmits without contact, according to the invention. An antenna 5 is connected to an input 16 of an analog receiving unit 1. An output 6 of the analog receiving unit is connected to a decoder 2 and to an (first) input 8 of a calibration unit 4. An output 9 of the decoder 2 is connected to another (second) input 10 of the calibration unit 4. A first output 11 of the calibration unit 4 is connected to a parameter register 3 of the decoder 2.

However, the parameter register 3 could also be configured to be separate from the decoder 2. A second output 13 of the calibration unit is connected to a signal former 22. An output 15 of the signal former 22 is connected to the input 16 of the analog receiving unit 1.

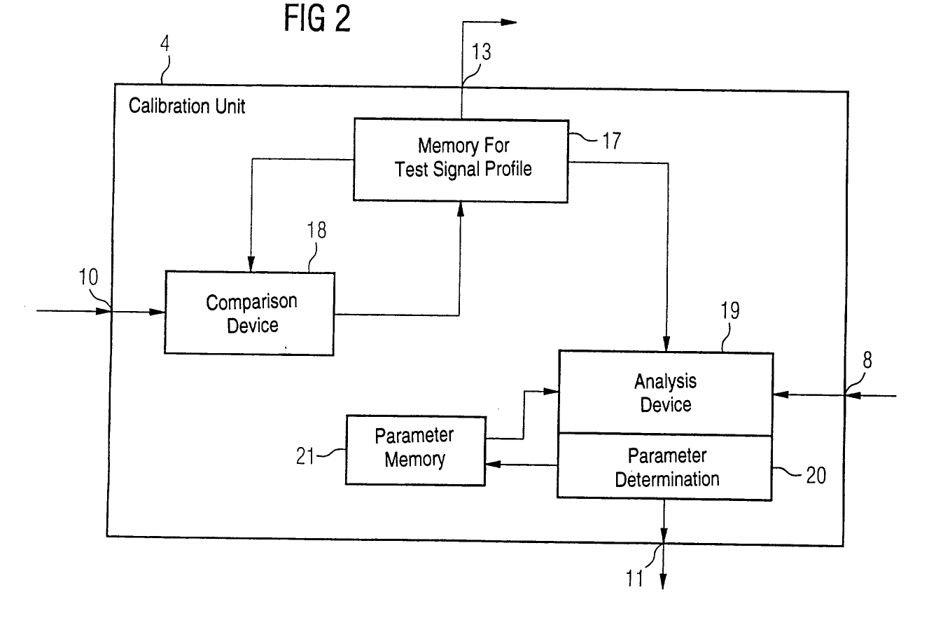

FIG. 2 shows a more detailed structure of the calibration unit 4 of FIG. 1. The calibration unit 4 has a memory 17, in which various test signal profiles are stored. Each test signal profile corresponds to a different transmitter. In this case, the test signal profile corresponds to a response signal from the transmitter, as it would transmit under real conditions to the apparatus for receiving digital data. The test signal profile is supplied via the second output 13 to the signal former 22, which represents an equivalent circuit for the antenna of the transmitter. This may include, for example, two capacitors and a coil. The signal former 22 feeds the signal, changed in accordance with the antenna characteristics, into the input 16 of the analog receiving unit 1. The analog receiving unit 1 distorts the test signal profile as a result of filters and amplifiers, and forwards the signal profile at its output 6 to the decoder 2 and to the calibration unit 4. The calibration unit 4 has an analysis device 19, which is connected to the first input 8 of the calibration unit. In the calibration unit 4, the output signal supplied by the analog receiving unit 1 is compared with the test signal profile. The test signal profile is transferred from the memory 17 to the analysis device 19 for this purpose.

The analysis of the distorted or possibly distorted test signal profile includes the determination of the filter propagation time of the analog receiving unit, a comparison of the number of signal peaks for determining overswings or the initial transient time of the filters, and the comparison of the widths of the signal peaks to determine the variance in the signal widths and the position of the peaks as compared with the test signal profile (by which the variance in the signal shift can be determined). From this, parameters are determined with which the decoder can be matched to the analog receiving unit and/or the characteristics of the transmitter. In order to match the decoder to the characteristics of the analog receiving unit, the parameters determined are firstly stored in a parameter memory 21 in the calibration unit 4, and secondly forwarded to the parameter register 3 via the first output 11.

The set quality of the decoder is checked by another test signal profile. In other words, an identical test signal profile is transferred from the memory 17 of the calibration unit 4 to the signal former 22. The analog receiving unit 1 distorts the test signal profile and in turn supplies the distorted test signal profile to the calibration unit 4 and to the decoder 2. The decoded test signal profile is fed via the second input 10 to a comparison device 18 of the calibration unit 4. The decoded test signal profile is compared with the test signal profile sent from the memory. In the event of a good agreement, the decoder has been matched well to the characteristics of the analog receiving unit by the parameter values determined.

If the comparison device establishes that there are still great differences between the decoded test signal profile and the test signal profile in the memory, a further pass is started. This iterative test sequence is run through until the decoded test data signal matches approximately with the test signal profile stored in the memory. During the iterative test sequences, the parameters determined in the previous pass can be called up from the parameter memory 21 and used for analysis.

However, with each new test sequence, new parameter values are determined by the analysis device 19, which are made available to the parameter memory 21 and to the parameter register 3 of the decoder.

The test data signals transmitted can be, for example, two bits in the “Manchester code”. In this digitally generated signal, all the signal peaks are equally long and have the same length. If the level of attenuation of the equivalent circuit were to be simulated, an additional signal might be transmitted to the signal former 22 (with which the characteristics of the signal former 22 can be changed).

Alternatively, the edges of the bits of the Manchester code can be varied. This makes it possible to simulate various distances between the transmitter and the analog receiving unit.

The invention is based on the principle that signal propagation times and shifts in the analog receiver unit can be found by determining parameters for the decoder on the basis of known test signal profiles, so that the decoder can use the information during decoding. This achieves a decoder rate that is significantly higher, when compared with the prior art.

The invention converts an apparatus for receiving digital data from a transmitter that transmits without contact from a statically fixed receiver to a dynamically adaptive system. In this case, an electrical equivalent circuit generates the transmission signal of a transmitter in the antenna field of the apparatus, by which parameter values for the decoder can be determined. Signal propagation times and signal shifts of the analog receiving units during decoding can be determined therefrom.

The parameters can be determined both during a new start of the apparatus and during operation. This makes it possible to compensate for any fluctuations of component parameters in the analog receiving unit, for example due to temperature fluctuations. For example, if the reader is to be changed over to another type of transmitter, parameters already determined can be called up from the parameter memory of the calibration unit and loaded into the parameter register of the decoder. If the parameter values of a transmitter are not yet present in the parameter memory, then they are determined and stored in the manner described.

However, using a signal former is not absolutely necessary. For example, the test signal profile could already be varied in the memory of the calibration unit in accordance with the characteristics of the antenna of the transmitter. In this case, direct feeding of the test signal profile into the analog receiving unit would be conceivable.

I claim:

1. An apparatus for receiving digital data from a transmitter transmitting without contact, comprising:
an analog receiving unit;
a decoder connected downstream of said analog receiving unit;
a signal former connected to said analog receiving unit for supplying a test signal profile to said analog receiving unit; and
a calibration unit connected to said analog receiving unit for determining parameters, based on a signal generated by said analog receiving unit, for matching said decoder to one of said analog receiving unit and the transmitter.

2. The apparatus according to claim 1, wherein said calibration unit contains a memory connected to said signal former for storing given signal profiles of the transmitter.

3. The apparatus according to claim 1, wherein said decoder includes a signal input and a signal output and said calibration unit is connected to said signal input and said signal output.

4. The apparatus according to claim 1, further comprising a parameter register coupled to said decoder and to said calibration unit.

5. The apparatus according to claim 4, wherein said parameter register is configured to be a part of said decoder.

6. The apparatus according to claim 1, wherein said calibration unit includes a parameter memory.

7. The apparatus according to claim 1, wherein said analog receiving unit includes an input and said signal former is an electrical equivalent circuit of the transmitter connected to said input of said analog receiving unit.

8. A method of matching an apparatus for receiving digital data to characteristics of a transmitter, the apparatus including an analog receiving unit and a decoder connected downstream of the analog receiving unit, the method comprising the steps of:
a) providing a test signal profile;
b) feeding the test signal profile to the analog receiving unit;
c) forwarding a distorted signal profile to a calibration unit;
d) analyzing the distorted signal profile and determining parameter values;
e) loading the parameter values into a parameter register; and
f) repeating steps a) to e) if necessary to conclude the method.

9. The method according to claim 8, which further comprises the step of: g) performing a comparison between an output signal of the decoder (2) and the test signal profile.

10. The method according to claim 9, which further comprises the step of repeating steps a) to g) in the event of a deviation between the output signal and the test signal profile.

11. The method according to claim 8, wherein the test signal profile reproduces a given signal profile of the transmitter.

12. The method according to claim 8, which further comprises the steps of:
storing the test signal profile in the calibration unit;
supplying the test signal profile to a signal former; and
feeding the test signal profile with the signal former to a signal input of the analog receiving unit.

13. The method according to claim 8, wherein the test signal profile contains an item of information for changing a level of attenuation.

14. The method according to claim 8, wherein the analyzing and determining step includes determining one of:
(i) a propagation time in the analog receiving unit;
(ii) overswings;
(iii) initial transient time;
(iv) a variance of signal widths; and
(v) a variance of a signal shift.

15. A method of matching an apparatus for receiving digital data to characteristics of a transmitter, the apparatus including an analog receiving unit and a decoder connected downstream of the analog receiving unit, the method comprising the steps of:
providing a test signal profile;
feeding the test signal profile to the analog receiving unit;
forwarding a distorted signal profile to a calibration unit;
analyzing the distorted signal profile and determining parameter values; and
loading the parameter values into a parameter register.
